(19) United States
(12) Patent Application Publication
(10) Pub. No.: US 2025/0113515 A1
(43) Pub. Date: Apr. 3, 2025

(54) SEMICONDUCTOR STRUCTURE AND MANUFACTURING METHOD THEREFOR

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/522,901

(22) Filed: Nov. 29, 2023

(30) Foreign Application Priority Data
Sep. 28, 2023 (CN) 202311277902.5

(51) Int. Cl. H01L 29/66; H01L 29/16; H01L 29/20; H01L 29/778

(52) U.S. Cl. CPC H10D 30/015; H10D 30/475; H10D 62/8325; H10D 62/8503

(57) ABSTRACT

Disclosed are a semiconductor structure and a manufacturing method therefor. The semiconductor structure includes: a substrate, a channel layer, and a barrier layer that are sequentially stacked. The substrate includes a plurality of spaced P-type semiconductor regions, each P-type semiconductor region of the plurality of spaced P-type semiconductor regions is in a strip shape, and an extension direction of the P-type semiconductor region is parallel to a channel length direction. In the present disclosure, the plurality of spaced P-type semiconductor regions that their extension directions are parallel to the channel length direction are disposed, which may convert a two-dimensional electron gas into an one-dimensional electron gas, and improve a linearity of a device.

### CROSS-REFERENCE TO RELATED APPLICATIONS

The present application claims priority to Chinese Patent Application No. 202311277902.5, filed on Sep. 28, 2023, which is hereby incorporated by reference in its entirety.

### TECHNICAL FIELD

The present disclosure relates to the field of semiconductor technologies, and in particular, to a semiconductor structure and a manufacturing method for the semiconductor structure.

### BACKGROUND

A High Electron Mobility Transistor (HEMT) is a heterojunction field effect transistor. Taking an AlGaN/GaN heterostructure as an example, because there is a relatively strong two-dimensional electron gas in the AlGaN/GaN heterostructure, an AlGaN/GaN HEMT is generally a depletion-mode device, so that an enhancement-mode device is not easy to implement. However, there is a limitation in application of the depletion-mode device in many scenes. For example, in application of a power switching device, an enhancement-mode (normally off) switching device is required. An enhancement-mode gallium nitride switching device is mainly used in a high-frequency device, a power switching device, a digital circuit, and the like, and research for the enhancement-mode gallium nitride switching device is of great significance.

Currently, a common enhancement-mode gallium nitride high electron mobility transistor device has a poor linearity, and cannot meet actual engineering application requirements.

### SUMMARY

In view of this, embodiments of the present disclosure provide a semiconductor structure and a manufacturing method therefor, so as to improve a linearity of an enhancement-mode gallium nitride high electron mobility transistor device.

According to an aspect of the present disclosure, an embodiment of the present disclosure provides a semiconductor structure, which includes:
a substrate, a channel layer, and a barrier layer that are sequentially stacked,
where the substrate includes a plurality of spaced P-type semiconductor regions, each P-type semiconductor region of the plurality of spaced P-type semiconductor regions is in a strip shape, and an extension direction of the P-type semiconductor region is parallel to a channel length direction.

As an optional embodiment, a thickness of the P-type semiconductor region is less than or equal to a thickness of the substrate.

As an optional embodiment, a position relationship between the P-type semiconductor region and the substrate includes any one of following position relationships:
the P-type semiconductor region is located inside the substrate, and an upper surface, close to the channel layer, of the P-type semiconductor region, a lower surface, away from the channel layer, of the P-type semiconductor region, and sidewalls of the P-type semiconductor region, are surrounded by the substrate;
the P-type semiconductor region penetrates through the substrate, and the sidewalls of the P-type semiconductor region are surrounded by the substrate; and
the P-type semiconductor region partially penetrates through the substrate, and the lower surface, away from the channel layer, of the P-type semiconductor region, and the sidewalls of the P-type semiconductor region, are surrounded by the substrate.

As an optional embodiment, along a channel width direction, a width changing manner of the plurality of spaced P-type semiconductor regions includes at least one of following changing manners: periodically changing, gradually increasing, gradually decreasing, first increasing and then decreasing, or first decreasing and then increasing.

As an optional embodiment, the semiconductor structure further includes:
a dielectric layer, located on the barrier layer;
a source, located on the barrier layer;
a drain, located on the barrier layer; and
a gate, located on the dielectric layer and between the source and the drain.

As an optional embodiment, along the channel length direction, an overlapping length of projections, on the substrate, of the P-type semiconductor region and the gate is equal to a length of a projection, on the substrate, of the gate.

As an optional embodiment, along the channel length direction, an overlapping length of projections, on the substrate, of the P-type semiconductor region and the gate is less than a length of a projection, on the substrate, of the gate, and an overlapping portion of the projections, on the substrate, of the P-type semiconductor region and the gate is located on a side, close to the drain, of the gate.

As an optional embodiment, a width of the P-type semiconductor region at a position below a side, close to the drain, of the gate is greater than a width of the P-type semiconductor region at a position below a side, close to the source, of the gate.

As an optional embodiment, a width of the P-type semiconductor region gradually decreases along a direction from the gate to the drain.

As an optional embodiment, a P-type doped ion concentration of the P-type semiconductor region gradually decreases along a direction from the gate to the drain.

As an optional embodiment, a material of the dielectric layer includes at least one of a silicon nitride, an aluminum oxide, an aluminum nitride, and an aluminum oxynitride.

As an optional embodiment, a thickness of the channel layer is less than 1 μm.

As an optional embodiment, a material of the substrate is a semi-insulating SiC.

According to another aspect of the present disclosure, an embodiment of the present disclosure provides a manufacturing method for a semiconductor structure, which includes:
forming a plurality of spaced P-type semiconductor regions in a substrate; and
sequentially stacking a channel layer and a barrier layer on the substrate,
where each P-type semiconductor region of the plurality of spaced P-type semiconductor regions is in a strip shape, and an extension direction of the P-type semiconductor region is parallel to a channel length direction.

As an optional embodiment, a method for forming the plurality of spaced P-type semiconductor regions includes ion implantation.

As an optional embodiment, an implanted ion of the ion implantation includes at least one of an aluminum ion, a magnesium ion, or a zinc ion.

As an optional embodiment, the forming a plurality of spaced P-type semiconductor regions in a substrate includes: etching a plurality of trenches in the substrate; and growing a P-type semiconductor material in each trench of the plurality of trenches by a selective epitaxy process, to form the plurality of spaced P-type semiconductor regions.

As an optional embodiment, the manufacturing method for the semiconductor structure further includes:
forming a dielectric layer, a source and a drain on the barrier layer, and forming a gate on the dielectric layer and between the source and the drain.

### BRIEF DESCRIPTION OF THE DRAWINGS

FIG. 1 is a schematic structural diagram of a semiconductor structure according to an embodiment of the present disclosure.

FIG. 2 is a schematic top view of a semiconductor structure according to an embodiment of the present disclosure.

FIG. 3a to FIG. 3c are schematic side views of semiconductor structures according to some embodiments of the present disclosure.

FIG. 4a to FIG. 4e are schematic top views of semiconductor structures according to some embodiments of the present disclosure.

FIG. 5a to FIG. 5b are schematic top views of semiconductor structures according to some embodiments of the present disclosure.

FIG. 6 is a schematic top view of a semiconductor structure according to an embodiment of the present disclosure.

FIG. 7 is a schematic top view of a semiconductor structure according to an embodiment of the present disclosure.

FIG. 8 is a schematic flowchart of a manufacturing method for a semiconductor structure according to an embodiment of the present disclosure.

FIG. 9 to FIG. 12 are schematic structural diagrams of intermediate structures corresponding to a semiconductor structure according to an embodiment of the present disclosure.

### DETAILED DESCRIPTION OF THE EMBODIMENTS

Technical solutions in embodiments of the present disclosure are described clearly and completely below with reference to the drawings of the embodiments of the present disclosure. Apparently, the described embodiments are only a part, but not all of the embodiments of the present disclosure. All other embodiments that may be obtained by those of ordinary skill in the art based on the embodiments in the present disclosure without any inventive efforts fall into the protection scope of the present disclosure.

To improve a linearity of an enhancement-mode gallium nitride high electron mobility transistor device, the present disclosure provides a semiconductor structure, which includes a substrate, a channel layer, and a barrier layer that are sequentially stacked. The substrate includes a plurality of spaced P-type semiconductor regions, each P-type semiconductor region of the plurality of spaced P-type semiconductor regions is in a strip shape, and an extension direction of the P-type semiconductor region is parallel to a channel length direction. In the present disclosure, the plurality of spaced P-type semiconductor regions that their extension directions are parallel to the channel length direction are disposed, which may convert a two-dimensional electron gas into an one-dimensional electron gas, so that different threshold voltages are formed at different positions of the channel layer, the device may be gradually opened along a channel width direction, and a decrease of a transconductance curve in a case of a relatively large drain current may be slowed down, thereby improving a transconductance flatness of the device, and further improving a linearity of the device.

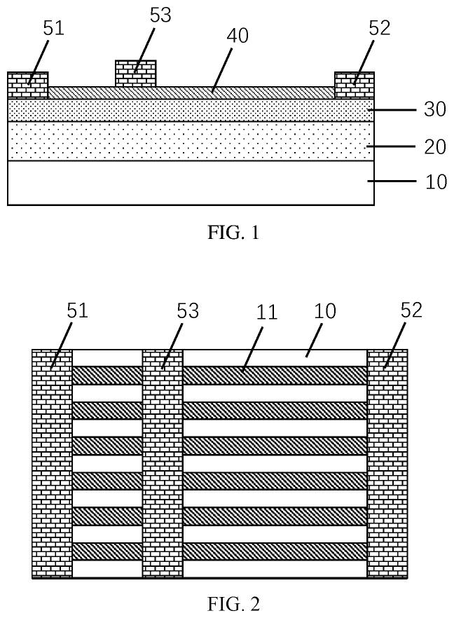

A semiconductor structure and a manufacturing method therefor, mentioned in the present disclosure, are illustrated with examples below with reference to FIG. 1 to FIG. 12.

FIG. 1 is a schematic structural diagram of a semiconductor structure according to an embodiment of the present disclosure. FIG. 2 is a schematic top view of a semiconductor structure according to an embodiment of the present disclosure. As shown in FIG. 1, the semiconductor structure includes: a substrate 10, a channel layer 20, and a barrier layer 30 that are sequentially stacked. The substrate 10 includes a plurality of spaced P-type semiconductor regions 11, each P-type semiconductor region 11 is in a strip shape, and an extension direction of the P-type semiconductor region 11 is parallel to a channel length direction (as shown in FIG. 2). As shown in FIG. 1, the semiconductor structure further includes: a dielectric layer 40, located on the barrier layer 30; a source 51, located on the barrier layer 30; a drain 52, located on the barrier layer 30; and a gate 53, located on the dielectric layer 40 and between the source 51 and the drain 52.

In this embodiment, a material of the substrate 10 may be a semi-insulating SiC. As a substrate, the semi-insulating SiC is a preferred material for GaN heteroepitaxy, a lattice mismatch between materials of SiC and GaN is only 3.4%, and SiC has an ultra-high thermal conductivity. Materials of the channel layer 20 and the barrier layer 30 include a material of a group III nitride. A two-dimensional electron gas may be formed at an interface between the channel layer 20 and the barrier layer 30. In an optional solution, the channel layer 20 is a GaN layer, and the barrier layer 30 is an AlGaN layer. In another optional solution, a material combination of the channel layer 20 and the barrier layer 30 may further be GaN/AlN, GaN/InN, GaN/InAlGaN, GaAs/AlGaAs, GaN/InAlN, or InN/InAlN. A thickness of the channel layer 20 may be less than 1 μm. In an optional solution, the thickness of the channel layer 20 is less than 300 nm. In another optional solution, the thickness of the channel layer 20 is less than 100 nm. The thickness of the channel layer 20 may be reduced to improve a density of the two-dimensional electron gas.

In this embodiment, a material of the dielectric layer 40 includes at least one of a silicon nitride, an aluminum oxide, an aluminum nitride, and an aluminum oxynitride. The material of the dielectric layer 40 has a strong capability for binding a charge. In a formed external electric field, a charge is not easily polarized, and a polarized charge is less, so that a polarized electric field is weak, and a short channel effect of the semiconductor structure is effectively avoided. The dielectric layer 40 is disposed to form a Metal-Insulator-Semiconductor (MIS) gate structure, which may effectively reduce a gate leakage current, increase a gate voltage swing and a drain current swing, and further improve a linear performance of the device.

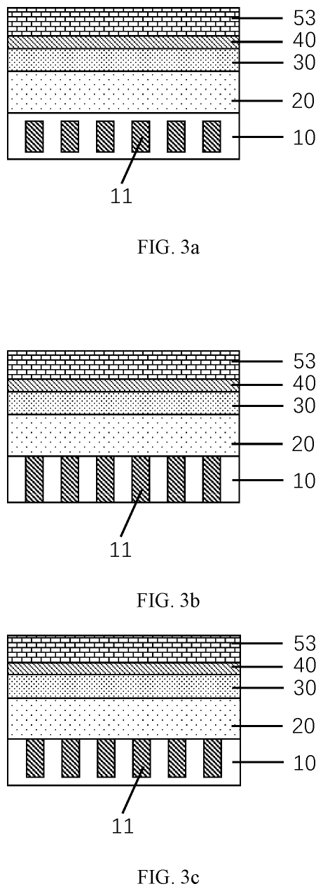

In an embodiment, FIG. 3a to FIG. 3c are schematic side views of semiconductor structures according to some embodiments of the present disclosure. A thickness of the P-type semiconductor region 11 is less than or equal to a thickness of the substrate 10. A position relationship between the P-type semiconductor region 11 and the substrate 10 includes any one of following position relationships: the P-type semiconductor region 11 is located inside the substrate 10, and an upper surface, close to the channel layer 20, of the P-type semiconductor region 11, a lower surface, away from the channel layer 20, of the P-type semiconductor region 11, and sidewalls of the P-type semiconductor region 11, are surrounded by the substrate 10 (as shown in FIG. 3a); the P-type semiconductor region 11 penetrates through the substrate 10, and the sidewalls of the P-type semiconductor region 11 are surrounded by the substrate 10 (as shown in FIG. 3b); and the P-type semiconductor region 11 partially penetrates through the substrate 10, and the lower surface, away from the channel layer 20, of the P-type semiconductor region 11, and the sidewalls of the P-type semiconductor region 11, are surrounded by the substrate 10 (as shown in FIG. 3c). When the P-type semiconductor region 11 is located inside the substrate 10, crystal quality of a surface of the substrate 10 is relatively well, which facilitates subsequent growth of an epitaxial layer; and when the P-type semiconductor region 11 penetrates through the substrate 10, the two-dimensional electron gas is depleted more thoroughly by the P-type semiconductor region 11, thereby further improving a linearity of the device.

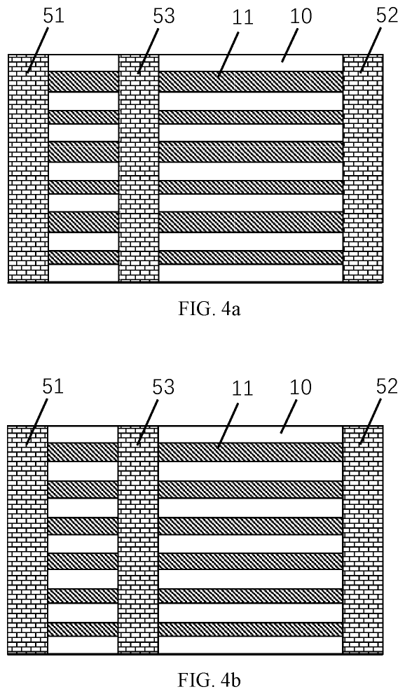

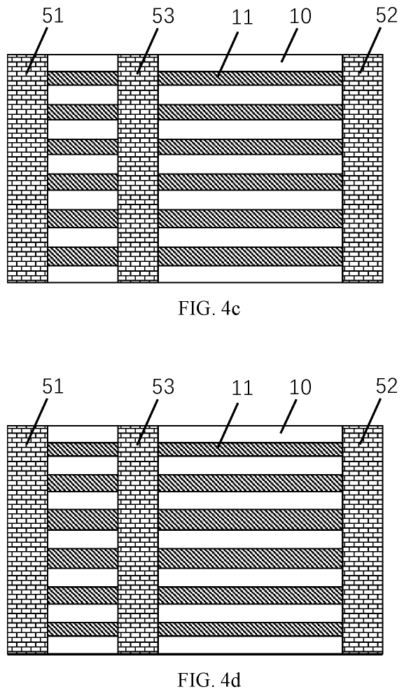

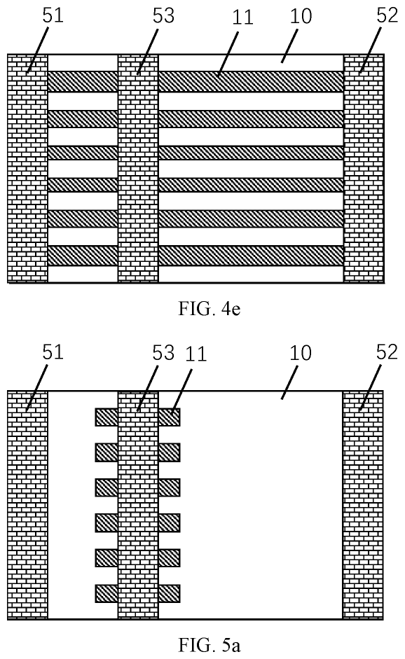

In an embodiment, FIG. 4a to FIG. 4e are schematic top views of semiconductor structures according to some embodiments of the present disclosure. Along a channel width direction, a width changing manner of a plurality of P-type semiconductor regions 11 includes at least one of following changing manners: periodically changing (as shown in FIG. 4a), gradually increasing (as shown in FIG. 4b), gradually decreasing (as shown in FIG. 4c), first increasing and then decreasing (as shown in FIG. 4d), or first decreasing and then increasing (as shown in FIG. 4e). The width changing manner of the plurality of P-type semiconductor regions 11 is not specifically limited in the present disclosure. By changing widths of the plurality of P-type semiconductor regions 11, that is, changing a proportion and a distribution of the plurality of P-type semiconductor regions 11 in the substrate 10, coupling of different gate control capabilities and different threshold voltages is provided, thereby improving a linearity of a semiconductor device.

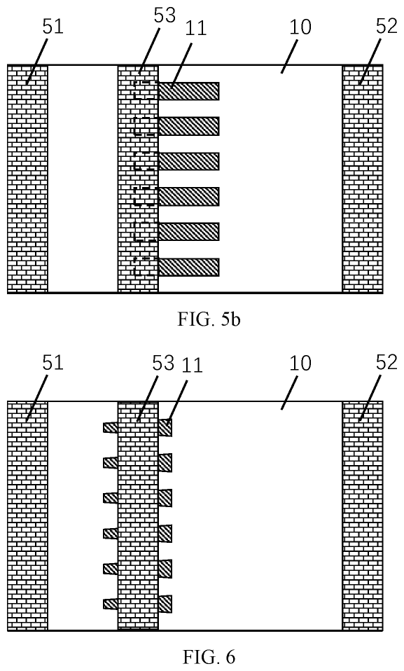

In an embodiment, FIG. 5a to FIG. 5b are schematic top views of semiconductor structures according to some embodiments of the present disclosure. As shown in FIG. 5a, a length of the P-type semiconductor region 11 is greater than or equal to a length of the gate 53 along the channel length direction, and along the channel length direction, an overlapping length of projections, on the substrate 10, of the P-type semiconductor region 11 and the gate 53 is equal to a length of a projection, on the substrate 10, of the gate 53. By designing the length of the P-type semiconductor region 11, a two-dimensional electron gas depletion region between the channel layer 20 and the barrier layer 30 may be regulated, thereby adjusting the linearity of the semiconductor device. The P-type semiconductor region 11 is designed to be located below the gate 53, so that the device may be gradually opened along the channel width direction, which may slow down a decrease of a transconductance curve in a case of a relatively large drain current, thereby improving a transconductance flatness of the device, and further improving the linearity of the device. As shown in FIG. 5b, along the channel length direction, an overlapping length of projections, on the substrate 10, of the P-type semiconductor region 11 and the gate 53 is less than a length of a projection, on the substrate 10, of the gate 53, and an overlapping portion of the projections, on the substrate 10, of the P-type semiconductor region 11 and the gate 53 is located on a side, close to the drain 52, of the gate 53. The P-type semiconductor region 11 is located below a side, close to the drain 52, of the gate 53, which may reduce a peak value of an electric field of a side, close to the drain 52, of the gate 53, thereby effectively improving a breakdown voltage of the semiconductor structure.

In an embodiment, FIG. 6 is a schematic top view of a semiconductor structure according to an embodiment of the present disclosure. As shown in FIG. 6, a width of the P-type semiconductor region 11 at a position below a side, close to the drain 52, of the gate 53 is greater than a width of the P-type semiconductor region 11 at a position below a side, close to a source 51, of the gate 53. A width of the P-type semiconductor region 11 below a side, close to the drain 52, of the gate 53 increases, that is, a width of the channel layer 20 below the side, close to the drain 52, of the gate 53 decreases, thereby reducing a peak electric field, avoiding breakdown caused by the peak electric field, and improving a breakdown voltage of the device.

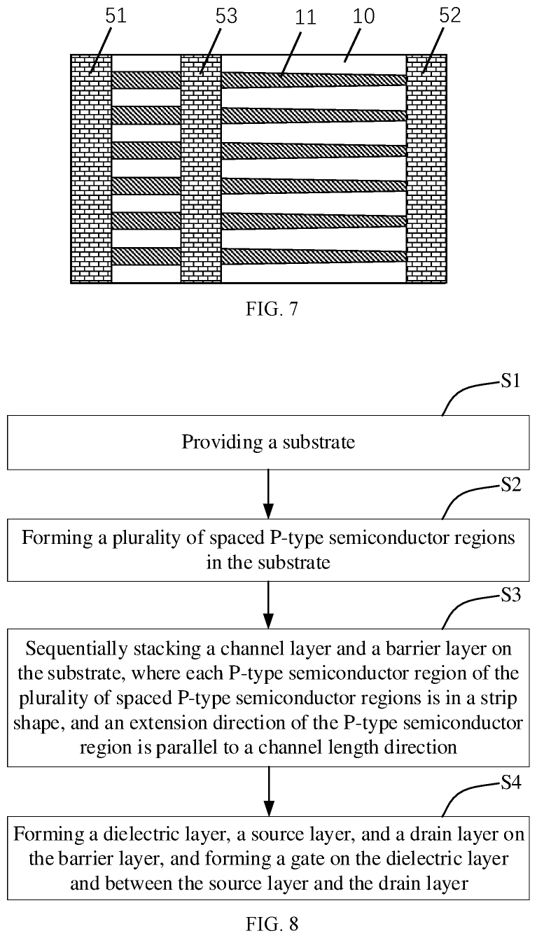

In an embodiment, FIG. 7 is a schematic top view of a semiconductor structure according to an embodiment of the present disclosure. As shown in FIG. 7, along a direction from the gate 53 to the drain 52, a width of the P-type semiconductor region 11 gradually decreases. Along the direction from the gate 53 to the drain 52, a P-type doped ion concentration of the P-type semiconductor region 11 may also gradually decrease. The width or the P-type doped ion concentration of the P-type semiconductor region 11 below a side, close to the drain 52, of the gate 53 is the largest, that is, a depletion degree of the two-dimensional electron gas below a side, close to the drain 52, of the gate 53 is the largest, thereby effectively reducing a peak value of an electric field of a side, close to the drain 52, of the gate 53 and effectively improving a breakdown voltage of the semiconductor structure. Along the direction from the gate 53 to the drain 52, the width or the P-type doped ion concentration of the P-type semiconductor region 11 gradually decreases, that is, a depletion effect on the two-dimensional electron gas decreases, so that a low channel on-resistance is maintained, and requirements of modulating an electric field intensity and improving a breakdown voltage of the device are met.

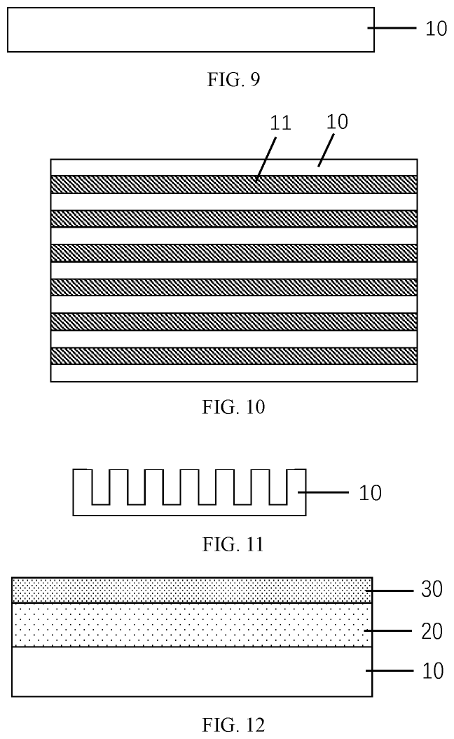

An embodiment of the present disclosure further provides a manufacturing method for a semiconductor structure. FIG. 8 is a schematic flowchart of a manufacturing method for a semiconductor structure according to an embodiment of the present disclosure. FIG. 9 to FIG. 12 are schematic structural diagrams of intermediate structures corresponding to a semiconductor structure according to an embodiment of the present disclosure. As shown in FIG. 8, a manufacturing method for a semiconductor structure includes following content.

Step S1: as shown in FIG. 9, providing a substrate 10.

A material of the substrate 10 may be a semi-insulating SiC. As a substrate, the semi-insulating SiC is a preferred material for GaN heteroepitaxy, a lattice mismatch between materials of SiC and GaN is only 3.4%, and SiC has an ultra-high thermal conductivity.

Step S2: as shown in FIG. 10, forming a plurality of spaced P-type semiconductor regions 11 in the substrate 10.

In an optional solution, a method for forming the plurality of spaced P-type semiconductor regions 11 includes ion implantation, where an implanted ion of the ion implantation includes at least one of an aluminum ion, a magnesium ion, or a zinc ion, and an intermediate structure shown in FIG. 10 is formed by the ion implantation. In another optional solution, a method for forming the plurality of spaced P-type semiconductor regions 11 includes: etching a trench in the substrate 10 and growing a P-type semiconductor material in the trench by a selective epitaxy process. The trench is etched in the substrate 10. As shown in FIG. 11, the P-type semiconductor material is grown in the trench by an in-situ doping selective epitaxy process, and the intermediate structure shown in FIG. 10 may also be formed. By using the in-situ doping selective epitaxy process, impurity ions in the formed P-type semiconductor region 11 may be uniformly distributed, and a width of the formed P-type semiconductor region 11 may be well controlled.

Step S3: as shown in FIG. 12, sequentially stacking a channel layer 20 and a barrier layer 30 on the substrate 10, where each P-type semiconductor region 11 of the plurality of spaced P-type semiconductor regions 11 is in a strip shape, and an extension direction of the P-type semiconductor region 11 is parallel to a channel length direction.

Growth of the channel layer 20 and the barrier layer 30 may be implemented by in-situ growth, or may be implemented by any one of Atomic Layer Deposition (ALD), Chemical Vapor Deposition (CVD), Molecular Beam Epitaxy (MBE), Plasma Enhanced Chemical Vapor Deposition (PECVD), Low Pressure Chemical Vapor Deposition (LPCVD), Metal-Organic Chemical Vapor Deposition (MOCVD), or a combination thereof. The plurality of spaced P-type semiconductor regions 11 that their extension directions are parallel to a channel length direction may convert a two-dimensional electron gas into an one-dimensional electron gas, so that different threshold voltages are formed at different positions of the channel layer, and a device may be gradually opened along a channel length direction, thereby slowing down a decrease of a transconductance curve in a case of a relatively large drain current, improving a transconductance flatness of the device, and further improving a linearity of the device.

Furtherly, the manufacturing method for a semiconductor structure further includes step S4: forming a dielectric layer 40, a source layer 51 and a drain layer 52 on the barrier layer 30, and forming a gate 53 on the dielectric layer 40 and between the source layer 51 and the drain layer 52, to form the semiconductor structure shown in FIG. 1.

In an embodiment, a thickness of the P-type semiconductor region 11 is less than or equal to a thickness of the substrate 10, and a position relationship between the P-type semiconductor region 11 and the substrate 10 includes any one of following position relationships: the P-type semiconductor region 11 is located inside the substrate 10, and an upper surface, close to the channel layer 20, of the P-type semiconductor region 11, a lower surface, away from the channel layer 20, of the P-type semiconductor region 11, and sidewalls of the P-type semiconductor region 11, are surrounded by the substrate 10 (as shown in FIG. 3a); the P-type semiconductor region 11 penetrates through the substrate 10, and the sidewalls of the P-type semiconductor region 11 are surrounded by the substrate 10 (as shown in FIG. 3b); and the P-type semiconductor region 11 partially penetrates through the substrate 10, and the lower surface, away from the channel layer 20, of the P-type semiconductor region 11, and the sidewalls of the P-type semiconductor region 11, are surrounded by the substrate 10 (as shown in FIG. 3c). When the P-type semiconductor region 11 is located inside the substrate 10, crystal quality of a surface of the substrate 10 is relatively well, which facilitates subsequent growth of an epitaxial layer; and when the P-type semiconductor region 11 penetrates through the substrate 10, the two-dimensional electron gas is depleted more thoroughly by the P-type semiconductor region 11, thereby further improving the linearity of the device.

In an embodiment, along a channel width direction, a width changing manner of the plurality of P-type semiconductor regions 11 includes at least one of following changing manners: periodically changing (as shown in FIG. 4a), gradually increasing (as shown in FIG. 4b), gradually decreasing (as shown in FIG. 4c), first increasing and then decreasing (as shown in FIG. 4d), or first decreasing and then increasing (as shown in FIG. 4e). The width changing manner of the plurality of P-type semiconductor regions 11 is not specifically limited in the present disclosure. By changing widths of the plurality of P-type semiconductor regions 11, that is, changing a proportion and a distribution of the plurality of P-type semiconductor regions 11 in the substrate 10, coupling of different gate control capabilities and different threshold voltages is provided, thereby improving a linearity of a semiconductor device.

In an embodiment, as shown in FIG. 5a, a length of the P-type semiconductor region 11 is greater than or equal to a length of the gate 53 along the channel length direction, and along the channel length direction, an overlapping length of projections, on the substrate 10, of the P-type semiconductor region 11 and the gate 53 is equal to a length of a projection, on the substrate 10, of the gate 53. By designing a length of the P-type semiconductor region 11, a two-dimensional electron gas depletion region between the channel layer 20 and the barrier layer 30 may be regulated, thereby adjusting the linearity of the semiconductor device. The P-type semiconductor region 11 is designed to be located below the gate 53, so that the device may be gradually opened along the channel width direction, which may slow down a decrease of a transconductance curve in a case of a relatively large drain current, thereby improving a transconductance flatness of the device, and further improving the linearity of the device. As shown in FIG. 5b, along the channel length direction, an overlapping length of projections, on the substrate 10, of the P-type semiconductor region 11 and the gate 53 is less than a length of a projection, on the substrate 10, of the gate 53, and an overlapping portion of the projections, on the substrate 10, of the P-type semiconductor region 11 and the gate 53 is located on a side, close to the drain 52, of the gate 53. The P-type semiconductor region 11 is located below a side, close to the drain 52, of the gate 53, which may reduce a peak value of an electric field of a side, close to the drain 52, of the gate 53, thereby effectively improving a breakdown voltage of the semiconductor structure.

In an embodiment, as shown in FIG. 6, a width of the P-type semiconductor region 11 at a position below a side, close to the drain 52, of the gate 53 is greater than a width of the P-type semiconductor region 11 at a position below a side, close to the source 51, of the gate 53. A width of the P-type semiconductor region 11 below a side, close to the drain 52, of the gate 53 increases, that is, a width of a channel layer 20 below the side, close to the drain 52, of the gate 53 decreases, thereby reducing a peak electric field, avoiding breakdown caused by the peak electric field, and improving a breakdown voltage of the device.

In an embodiment, as shown in FIG. 7, along a direction from the gate 53 to the drain 52, a width of the P-type semiconductor region 11 gradually decreases. Along the direction from the gate 53 to the drain 52, a P-type doped ion concentration of the P-type semiconductor region 11 may also gradually decrease. The width or the P-type doped ion concentration of the P-type semiconductor region 11 below a side, close to the drain 52, of the gate 53 is the largest, that is, a depletion degree of the two-dimensional electron gas below a side, close to the drain 52, of the gate 53 is the largest, thereby effectively reducing a peak value of an electric field of a side, close to the drain 52, of the gate 53 and effectively improving a breakdown voltage of the semiconductor structure. Along the direction from the gate 53 to the drain 52, the width or the P-type doped ion concentration of the P-type semiconductor region 11 gradually decreases, that is, a depletion effect on the two-dimensional electron gas decreases, so that a low channel on-resistance is maintained, and requirements of modulating an electric field intensity and improving a breakdown voltage of the device are met.

The present disclosure provides a semiconductor structure, which includes a substrate, a channel layer, and a barrier layer that are sequentially stacked. The substrate includes a plurality of spaced P-type semiconductor regions, each P-type semiconductor region is in a strip shape, and an extension direction of the P-type semiconductor region is parallel to a channel length direction.

In the present disclosure, a P-type semiconductor region disposed in a substrate may implement depletion of a two-dimensional electron gas between a channel layer and a barrier layer, and avoid damage to the barrier layer caused by etching the P-type semiconductor layer after the P-type semiconductor layer is fabricated on the barrier layer.

In the present disclosure, a plurality of spaced P-type semiconductor regions that their extension directions are parallel to a channel length direction are disposed, which may convert a two-dimensional electron gas into an one-dimensional electron gas, so that different threshold voltages are formed at different positions of a channel layer, a device may be gradually opened along a channel width direction, and a decrease of a transconductance curve in a case of a relatively large drain current may be slowed down, thereby improving a transconductance flatness of the device, and further improving a linearity of the device.

In the present disclosure, a structure of a semiconductor structure is simple, a manufacturing process is easy to control, costs are relatively low, and a reliability of a formed device is high.

It should be understood that the term “including” and its modification used in this disclosure are open-ended, that is, “including but not limited to”. The term “an embodiment” represents “at least one embodiment”; the term “another embodiment” means “at least one another embodiment”. In this specification, a schematic description of foregoing terms does not have to be directed to a same embodiment or example. Further, specific features, structures, materials, or features described may be incorporated in an appropriate manner in any one or more embodiments or examples. In addition, without being contradictory, a person skilled in the art may combine and permutate different embodiments or examples described in this specification and features of different embodiments or examples.

The foregoing descriptions are merely exemplary embodiments of the present disclosure, and are not intended to limit the present disclosure. Any modification, an equivalent replacement, or the like made within a spirit and principles of the present disclosure shall be included in a protection scope of the present disclosure.

What is claimed is:

1. A semiconductor structure, comprising:
a substrate, a channel layer, and a barrier layer that are sequentially stacked,
wherein the substrate comprises a plurality of spaced P-type semiconductor regions, each P-type semiconductor region of the plurality of spaced P-type semiconductor regions is in a strip shape, and an extension direction of the P-type semiconductor region is parallel to a channel length direction.

2. The semiconductor structure according to claim 1, wherein a thickness of the P-type semiconductor region is less than or equal to a thickness of the substrate.

3. The semiconductor structure according to claim 2, wherein a position relationship between the P-type semiconductor region and the substrate comprises any one of following position relationships:
the P-type semiconductor region is located inside the substrate, and an upper surface, close to the channel layer, of the P-type semiconductor region, a lower surface, away from the channel layer, of the P-type semiconductor region, and sidewalls of the P-type semiconductor region, are surrounded by the substrate;
the P-type semiconductor region penetrates through the substrate, and the sidewalls of the P-type semiconductor region are surrounded by the substrate; and
the P-type semiconductor region partially penetrates through the substrate, and the lower surface, away from the channel layer, of the P-type semiconductor region, and the sidewalls of the P-type semiconductor region, are surrounded by the substrate.

4. The semiconductor structure according to claim 1, wherein along a channel width direction, a width changing manner of the plurality of spaced P-type semiconductor regions comprises at least one of following changing manners: periodically changing, gradually increasing, gradually decreasing, first increasing and then decreasing, or first decreasing and then increasing.

5. The semiconductor structure according to claim 1, further comprising:
a dielectric layer, located on the barrier layer;
a source, located on the barrier layer;
a drain, located on the barrier layer; and
a gate, located on the dielectric layer and between the source and the drain.

6. The semiconductor structure according to claim 5, wherein along the channel length direction, an overlapping length of projections, on the substrate, of the P-type semiconductor region and the gate is equal to a length of a projection, on the substrate, of the gate.

7. The semiconductor structure according to claim 5, wherein along the channel length direction, an overlapping length of projections, on the substrate, of the P-type semiconductor region and the gate is less than a length of a projection, on the substrate, of the gate, and an overlapping portion of the projections, on the substrate, of the P-type semiconductor region and the gate is located on a side, close to the drain, of the gate.

8. The semiconductor structure according to claim 5, wherein a width of the P-type semiconductor region at a position below a side, close to the drain, of the gate is greater than a width of the P-type semiconductor region at a position below a side, close to the source, of the gate.

9. The semiconductor structure according to claim 5, wherein a width of the P-type semiconductor region gradually decreases along a direction from the gate to the drain.

10. The semiconductor structure according to claim 5, wherein a P-type doped ion concentration of the P-type semiconductor region gradually decreases along a direction from the gate to the drain.

11. The semiconductor structure according to claim 5, wherein a material of the dielectric layer comprises at least one of a silicon nitride, an aluminum oxide, an aluminum nitride, and an aluminum oxynitride.

12. The semiconductor structure according to claim 1, wherein a thickness of the channel layer is less than 1 μm.

13. The semiconductor structure according to claim 12, wherein the thickness of the channel layer is less than 100 nm.

14. The semiconductor structure according to claim 1, wherein a material of the substrate is a semi-insulating SiC.

15. The semiconductor structure according to claim 1, wherein a material combination of the channel layer and the barrier layer is GaN/AlGaN, GaN/AlN, GaN/InN, GaN/InAlGaN, GaAs/AlGaAs, GaN/InAlN, or InN/InAlN.

16. A manufacturing method for a semiconductor structure, comprising:
forming a plurality of spaced P-type semiconductor regions in a substrate; and
sequentially stacking a channel layer and a barrier layer on the substrate,
wherein each P-type semiconductor region of the plurality of spaced P-type semiconductor regions is in a strip shape, and an extension direction of the P-type semiconductor region is parallel to a channel length direction.

17. The manufacturing method for the semiconductor structure according to claim 16, wherein a method for forming the plurality of spaced P-type semiconductor regions comprises ion implantation.

18. The manufacturing method for the semiconductor structure according to claim 17, wherein an implanted ion of the ion implantation comprises at least one of an aluminum ion, a magnesium ion, or a zinc ion.

19. The manufacturing method for the semiconductor structure according to claim 16, wherein the forming a plurality of spaced P-type semiconductor regions in a substrate comprises:
etching a plurality of trenches in the substrate; and
growing a P-type semiconductor material in each trench of the plurality of trenches by a selective epitaxy process, to form the plurality of spaced P-type semiconductor regions.

20. The manufacturing method for the semiconductor structure according to claim 16, further comprising:
forming a dielectric layer, a source and a drain on the barrier layer, and forming a gate on the dielectric layer and between the source and the drain.
